(19) United States
(12) Patent Application Publication
(10) Pub. No.: US 2017/0179078 A1
(43) Pub. Date: Jun. 22, 2017

(54) SEMICONDUCTOR PACKAGES AND METHODS OF MANUFACTURING THE SAME

(71) Applicant: SK hynix Inc., Icheon-si Gyeonggi-do (KR)

(72) Inventors: Yeon Seung JUNG, Suwon-si (KR); Ho Young SON, Cheongju-si Chungcheongbuk-do (KR); Su Hyeon PARK, Icheon-si Gyeonggi-do (KR)

(21) Appl. No.: 15/160,178

(22) Filed: May 20, 2016

(30) Foreign Application Priority Data
Dec. 22, 2015 (KR) 10-2015-0184106

(51) Int. Cl. H01L 25/065; H01L 25/00

(52) U.S. Cl. CPC H01L 25/0652; H01L 25/50; H01L 2225/06572; H01L 2225/06548; H01L 2225/06558; H01L 2225/06513; H01L 2225/06596; H01L 2225/06589; H01L 2225/06586

(57) ABSTRACT

A semiconductor package and or method of fabricating the semiconductor package may be provided. The semiconductor package may include a first die, at least one second die electrically connected to the first die, and a plurality of first connectors disposed on the interconnection structure layer. The semiconductor package may include a package substrate electrically connected to the plurality of first connectors. The package substrate may have a cavity and the at least one second die is at least partially disposed in the cavity. The interconnection structure layer may include signal paths electrically connected to the first die and to the at least one second die. The at least one second die may be positioned to minimize a length of the signal paths.

### CROSS-REFERENCE TO RELATED APPLICATIONS

The present application claims priority under 35 U.S.C 119(a) to Korean Patent Application No. 10-2015-0184106, filed on Dec. 22, 2015, which is herein incorporated by references in its entirety.

### BACKGROUND

1. Technical Field

Embodiments of the present disclosure generally relate to semiconductor package technologies and, more particularly, to semiconductor packages including semiconductor chips vertically stacked and methods of manufacturing the same.

2. Related Art

Semiconductor packages which are capable of processing a large amount of data are increasingly in demand with the development of smaller electronic systems such as mobile systems. More specifically, semiconductor packages which are capable of processing a large amount of data at a time and executing various functions are increasingly in demand. In response to such a demand, each of the semiconductor packages are realized to include a plurality of semiconductor chips having different functions. System-in-package (SIP) techniques are a very attractive candidate for realizing semiconductor packages which are capable of processing large amounts of data at a time and executing various functions. Recently, the system-in-package (SIP) techniques for encapsulating a plurality of semiconductor chips having different functions in a single package have been proposed to realize high performance electronic systems. As a result of the SIP techniques, a lot of effort has been focused on realizing 2.5-dimensional (2.5D) or 3-dimensional (3D) SIPs, each of which includes at least one micro-processor chip and at least one memory chip, to improve functions of the semiconductor packages.

### SUMMARY

According to an embodiment, there is provided a method of manufacturing a semiconductor package. The method may include providing a dummy wafer. The method may include forming an interconnection structure layer on the dummy wafer. The method may include mounting a first die on the interconnection structure layer. The method may include forming a molding part on the interconnection structure layer to protect the first die. The method may include recessing the dummy wafer to expose a surface of the interconnection structure layer opposite to the first die. The method may include mounting at least one second die on one portion of the exposed surface of the interconnection structure layer to overlap with a portion of the first die. The method may include forming a plurality of first connectors on the other portion of the exposed surface of the interconnection structure layer. The method may include attaching a package substrate to the plurality of first connectors. The package substrate has a cavity therein and the at least one second die is partially or entirely disposed in the cavity. The interconnection structure layer may be provided to include first redistribution patterns extending substantially in a vertical direction to electrically connect the first die to the at least one second die, second redistribution patterns extending substantially in a horizontal direction to electrically connect the at least one second die to some of the plurality of first connectors, and third redistribution patterns electrically connecting the first die to the others of the plurality of first connectors.

According to an embodiment, there is provided a method of manufacturing a semiconductor package. The method may include providing a dummy wafer. The method may include forming an interconnection structure layer on the dummy wafer The method may include mounting a first die on the interconnection structure layer The method may include forming a first molding part on the interconnection structure layer to protect the first die The method may include recessing the dummy wafer to expose a surface of the interconnection structure layer opposite to the first die The method may include mounting at least one second die on one portion of the exposed surface of the interconnection structure layer to overlap with a portion of the first die The method may include forming a second molding part on the other portion of the exposed surface of the interconnection structure layer to surround the at least one second die The method may include forming a plurality of through mold vias penetrating the second molding part to be electrically connected to the interconnection structure layer The method may include attaching a package substrate to the plurality of through mold vias. The interconnection structure layer may be provided to include first redistribution patterns extending substantially in a vertical direction to electrically connect the first die to the at least one second die, second redistribution patterns extending substantially in a horizontal direction to electrically connect the at least one second die to some of the plurality of through mold vias, and third redistribution patterns electrically connecting the first die to the others of the plurality of through mold vias.

According to an embodiment, a semiconductor package may include a first die. The semiconductor package may include an interconnection structure layer electrically connected to the first die. The semiconductor package may include a plurality of first connectors disposed on the interconnection structure layer. The semiconductor package may include at least one second die disposed to overlap with a portion of the first die, and a package substrate electrically connected to the plurality of first connectors. The package substrate may include a cavity therein and the at least one second die is partially or entirely disposed in the cavity. The interconnection structure layer may be provided to include first redistribution patterns extending substantially in a vertical direction to electrically connect the first die to the at least one second die, second redistribution patterns extending substantially in a horizontal direction to electrically connect the at least one second die to some of the plurality of first connectors, and third redistribution patterns electrically connecting the first die to the others of the plurality of first connectors.

According to an embodiment, a semiconductor package may include a first die. The semiconductor package may include an interconnection structure layer electrically connected to the first die. The semiconductor package may include at least one second die disposed to overlap with a portion of the first die. The semiconductor package may include a molding part disposed on a surface of the interconnection structure layer to surround the at least one second die. The semiconductor package may include a plurality of through mold vias penetrating the molding part. The semiconductor package may include a package substrate electrically connected to the plurality of through mold vias. The interconnection structure layer may be provided to include first redistribution patterns extending substantially in a vertical direction to electrically connect the first die to the at least one second die, second redistribution patterns extending substantially in a horizontal direction to electrically connect the at least one second die to some of the plurality of through mold vias, and third redistribution patterns electrically connecting the first die to the others of the plurality of through mold vias.

According to an embodiment, there may be provided a memory card including a semiconductor package. The semiconductor package may include a first die. The semiconductor package may include an interconnection structure layer electrically connected to the first die. The semiconductor package may include a plurality of first connectors disposed on the interconnection structure layer. The semiconductor package may include at least one second die disposed to overlap with a portion of the first die, and a package substrate electrically connected to the plurality of first connectors. The package substrate may include a cavity therein and the at least one second die is partially or entirely disposed in the cavity. The interconnection structure layer may be provided to include first redistribution patterns extending substantially in a vertical direction to electrically connect the first die to the at least one second die, second redistribution patterns extending substantially in a horizontal direction to electrically connect the at least one second die to some of the plurality of first connectors, and third redistribution patterns electrically connecting the first die to the others of the plurality of first connectors.

According to an embodiment, there may be provided a memory card including a semiconductor package. The semiconductor package may include a first die. The semiconductor package may include an interconnection structure layer electrically connected to the first die. The semiconductor package may include at least one second die disposed to overlap with a portion of the first die. The semiconductor package may include a molding part disposed on a surface of the interconnection structure layer to surround the at least one second die. The semiconductor package may include a plurality of through mold vias penetrating the molding part. The semiconductor package may include a package substrate electrically connected to the plurality of through mold vias. The interconnection structure layer may be provided to include first redistribution patterns extending substantially in a vertical direction to electrically connect the first die to the at least one second die, second redistribution patterns extending substantially in a horizontal direction to electrically connect the at least one second die to some of the plurality of through mold vias, and third redistribution patterns electrically connecting the first die to the others of the plurality of through mold vias.

According to an embodiment, there may be provided an electronic system including a semiconductor package. The semiconductor package may include a first die. The semiconductor package may include an interconnection structure layer electrically connected to the first die. The semiconductor package may include a plurality of first connectors disposed on the interconnection structure layer. The semiconductor package may include at least one second die disposed to overlap with a portion of the first die, and a package substrate electrically connected to the plurality of first connectors. The package substrate may include a cavity therein and the at least one second die is partially or entirely disposed in the cavity. The interconnection structure layer may be provided to include first redistribution patterns extending substantially in a vertical direction to electrically connect the first die to the at least one second die, second redistribution patterns extending substantially in a horizontal direction to electrically connect the at least one second die to some of the plurality of first connectors, and third redistribution patterns electrically connecting the first die to the others of the plurality of first connectors.

According to an embodiment, there may be provided an electronic system including a semiconductor package. The semiconductor package may include a first die. The semiconductor package may include an interconnection structure layer electrically connected to the first die. The semiconductor package may include at least one second die disposed to overlap with a portion of the first die. The semiconductor package may include a molding part disposed on a surface of the interconnection structure layer to surround the at least one second die. The semiconductor package may include a plurality of through mold vias penetrating the molding part. The semiconductor package may include a package substrate electrically connected to the plurality of through mold vias. The interconnection structure layer may be provided to include first redistribution patterns extending substantially in a vertical direction to electrically connect the first die to the at least one second die, second redistribution patterns extending substantially in a horizontal direction to electrically connect the at least one second die to some of the plurality of through mold vias, and third redistribution patterns electrically connecting the first die to the others of the plurality of through mold vias.

The semiconductor package may include a first die, at least one second die electrically connected to the first die, and a plurality of first connectors disposed on the interconnection structure layer. The semiconductor package may include a package substrate electrically connected to the plurality of first connectors. The package substrate may have a cavity and the at least one second die is at least partially disposed in the cavity. The interconnection structure layer may include signal paths electrically connected to the first die and to the at least one second die. The at least one second die may be positioned to minimize a length of the signal paths.

A method of manufacturing a semiconductor package may be provided. The method may include providing a dummy wafer, forming an interconnection structure layer on the dummy wafer, connecting a first die on the interconnection structure layer, and forming a molding part on the interconnection structure layer to protect the first die. The method may include recessing the dummy wafer to expose a surface of the interconnection structure layer opposite to the first die, disposing at least one second die on one portion of the exposed surface of the interconnection structure layer, forming a plurality of first connectors on the other portion of the exposed surface of the interconnection structure layer, and connecting a package substrate to the plurality of first connectors. The package substrate may have a cavity therein and the second die is at least partially disposed in the cavity. The interconnection structure layer may include signal paths electrically connected to the first die and to the at least one second die. The at least one second die may be positioned to minimize a length of the signal paths.

### BRIEF DESCRIPTION OF THE DRAWINGS

FIGS. 1 to 5 illustrate representations of examples of a semiconductor package according to an embodiment.

FIG. 6 is a cross-sectional view illustrating a representation of an example of a semiconductor package according to an embodiment.

FIGS. 7 to 16 are cross-sectional views illustrating representations of examples of a method of manufacturing a semiconductor package according to an embodiment.

FIG. 17 is a cross-sectional view illustrating a representation of an example of a semiconductor package according to an embodiment.

FIGS. 18 to 22 are cross-sectional views illustrating representations of examples of a method of manufacturing a semiconductor package according to an embodiment.

FIG. 23 is a block diagram illustrating a representation of an example of an electronic system employing a memory card including a package according to an embodiment.

FIG. 24 is a block diagram illustrating a representation of an example of an electronic system including a package according to an embodiment.

### DETAILED DESCRIPTION

The terms used herein may correspond to words selected in consideration of their functions in the embodiments, and the meanings of the terms may be construed to be different according to ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong.

It will be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the description.

Semiconductor packages according to the following embodiments may correspond to system-in-packages (SIPs). Each of the semiconductor packages may be realized to include a plurality of semiconductor chips, at least two of which are designed to have different functions. The semiconductor chips may be obtained by separating a semiconductor substrate such as a wafer including electronic circuits into a plurality of pieces using a die sawing process. The semiconductor chip may have a package form including a package substrate and a semiconductor die mounted on the package substrate. In such a case, the semiconductor die may include an electronic circuit integrated therein. The semiconductor chip may include a plurality of semiconductor dies which are vertically stacked to have a three-dimensional structure, and the plurality of semiconductor dies may be electrically connected to each other using silicon through vias (TSVs) penetrating the plurality of semiconductor dies. The semiconductor chips may correspond to memory chips including, for example, dynamic random access memory (DRAM) circuits, static random access memory (SRAM) circuits, flash circuits, magnetic random access memory (MRAM) circuits, resistive random access memory (ReRAM) circuits, ferroelectric random access memory (FeRAM) circuits or phase change random access memory (PcRAM) circuits which are integrated on the semiconductor substrate. The semiconductor chips or the semiconductor packages may be employed in communication systems such as mobile phones, electronic systems associated with biotechnology or health care, or wearable electronic systems.

In some embodiments, the semiconductor chip may corresponds to a logic chip having a system-on-chip (SoC) form. The SoC may be an application specific integrated circuit (ASIC) chip including a microprocessor, a microcontroller, a digital signal processing core or an interface. The SoC may include a central processing unit (CPU) or a graphics processing unit (GPU). In order that the SoC operates at a high speed, the SoC has to communicate with a memory chip storing data at a high speed. That is, a short interface path and a high signal bandwidth may be required to improve an operation speed of the SoC. For example, if a GPU chip and a high bandwidth memory (HBM) chip are vertically stacked in a single SIP, an interface path between the GPU chip and the HBM chip may be reduced to improve an operation speed of the GPU chip.

In an electronic system, a bottleneck phenomenon in communication between a memory chip and a processor chip may degrade the performance of the electronic system. Accordingly, high performance memory chips such as HBM chips may be employed as memory chips of the electronic systems. The HBM chip may be configured to include a plurality of memory die which are vertically stacked using a TSV technique to obtain a high bandwidth thereof. The HBM chip may include a plurality of TSVs connected to each of the memory die to independently control the respective memory die which are vertically stacked. Each of the memory die may be configured to include two memory channels, and a plurality of TSVs, for example, one hundred and twenty eight TSVs acting as input/output (I/O) pins may be required for operation of each memory channel. Accordingly, an HBM chip comprised of four stacked memory die may include one thousand and twenty four TSVs to independently control eight memory channels. In such a case, one of the eight memory channels may independently communicate with another one of the eight memory channels through the TSVs. Thus, a signal bandwidth of the HBM chip may be broadened because each memory channel independently and directly receives or outputs signals through the TSVs. However, if the number of the TSVs increases to improve the bandwidth of the HBM chip, a pitch size of interconnection lines or pads included in the HBM chip may be reduced. Therefore, the following embodiments provide various SIPs having a configuration that electrically connects the memory chip to the ASIC chip using an interconnection structure layer realized with a wafer processing technique which is capable of forming fine patterns.

The same reference numerals refer to the same elements throughout the specification. Thus, even though a reference numeral is not mentioned or described with reference to a drawing, the reference numeral may be mentioned or described with reference to another drawing. In addition, even though a reference numeral is not illustrated in a drawing, it may be mentioned or described with reference to another drawing.

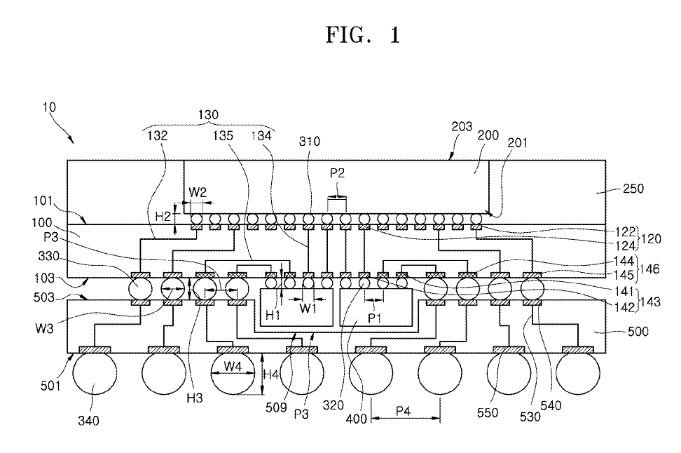

FIGS. 1 to 5 illustrate a semiconductor package 10 according to an embodiment.

FIG. 1 the semiconductor package 10 may be configured to include an interconnection structure layer 100, a first die 200 disposed on a top surface 101 of the interconnection structure layer 100, and second die 400 disposed on a bottom surface 103 of the interconnection structure layer 100 opposite to the first die 200. The semiconductor package 10 may be an integrated circuit (IC) package. The first die 200 and each second die 400 may have different functions to constitute a single system. In such a case, the semiconductor package 10 may be configured to have an SIP form.

The first die 200 may be disposed to be electrically connected to the interconnection structure layer 100. The first die 200 may include a semiconductor substrate (not illustrated), active devices (not illustrated) such as transistors, and interconnection lines (not illustrated). The active devices may be formed on the semiconductor substrate, and the interconnection lines may be formed on the active devices and the semiconductor substrate. The interconnection lines may be formed on the semiconductor substrate to include an interlayer dielectric (ILD) layer or an inter-metal dielectric (IMD) layer.

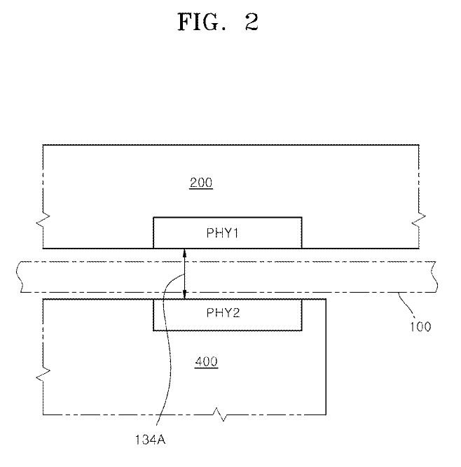

The first die 200 may be a microprocessor, a high performance central processing unit (CPU) or a high performance graphic processing unit (GPU). Referring to FIG. 2, the first die 200 may be disposed to overlap with at least a portion of each of the second die 400, and the interconnection structure layer 100 may be disposed between the first die 200 and each second die 400. The first die 200 may be vertically overlapped with each of the second die 400. The first die 200 may include an interface physical layer PHY1 for electrically communicating with the second die 400, and each of the second die 400 may also include an interface physical layer PHY2 for electrically communicating with the first die 200 (see FIG. 2). The first and second die 200 and 400 may be appropriately disposed on the interconnection structure layer 100 so that the interface physical layer PHY1 of the first die 200 vertically overlaps with the interface physical layers PHY2 of the second die 400. Since the interface physical layer PHY1 is located to vertically overlap with the interface physical layers PHY2, a length of a signal path 134A between the interface physical layer PHY1 and each of the interface physical layers PHY2 may be minimized to improve a signal transmission speed between the first die 200 and the second die 400. If the first die 200 includes a GPU device and each of the second die 400 includes a memory device, the first and second die 200 and 400 may communicate with each other at a high speed through the signal path 134A between the interface physical layers PHY1 and PHY2. As a result, the semiconductor package 10 may exhibit excellent characteristics with a high operation speed.

The semiconductor package 10 may include a package substrate 500 which is electrically and mechanically connected to the first die 200, the interconnection structure layer 100 and the second die 400. The package substrate 500 may have a top surface 503 on which the first and second dies 200 and 400 and the interconnection structure layer 100 are disposed. External connection terminals 340 may be disposed on a bottom surface 501 of the package substrate 500 opposite to the first and second dies 200 and 400 and the interconnection structure layer 100. The external connection terminals 340 may be solder balls or bumps.

The package substrate 500 may include package interconnection structures 530+540+550 acting as circuit interconnection lines for electrically connecting the first and second die 200 and 400 to an external device, unlike the semiconductor substrate on which integrated circuits are integrated. The package substrate 500 may include a dielectric body for electrically insulating the package interconnection structures 530+540+550 from each other. The package substrate 500 may be a printed circuit board (PCB) including the package interconnection structures 530+540+550 disposed in and on the dielectric body. The package interconnection structures 530+540+550 may include first package interconnection pads 540 that are disposed on the top surface 503 of the package substrate 500 and are electrically connected to the first and second die 200 and 400. The package interconnection structures 530+540+550 may include second package interconnection pads 550 combined with the external connection terminals 340 and package interconnection lines 530 for electrically connecting the first package interconnection pads 540 to the second package interconnection pads 550. The package interconnection lines 530 may be conductive members that substantially penetrate the substrate body of the package substrate 500. Since the second package interconnection pads 550 are respectively connected to the external connection terminals 340, the second package interconnection pads 550 may be disposed to have a pitch which is equal to a pitch P4 of the external connection terminals 340. The pitch P4 of the external connection terminals 340 may be set in consideration of a width W4 and a height H4 of the external connection terminals 340. Thus, a width of the second package interconnection pads 550 may also be set in consideration of the width W4 and the height H4 of the external connection terminals 340. The width and the pitch of the second package interconnection pads 550 may be set to be substantially greater than the width and the pitch of the first package interconnection pads 540, respectively.

A portion of the top surface 503 of the package substrate 500 may have a concave shape to provide a cavity 509 in the package substrate 500. In some embodiments, the cavity 509 may be provide to penetrate the package substrate 500. The second die 400 may be at least partially inserted into the cavity 509. That is, an entire portion or a portion of each of the second die 400 may be inserted into the cavity 509. Thus, a distance between the package substrate 500 and the interconnection structure layer 100 may be less than a height of the second die 400. That is, a distance between the top surface 503 of the package substrate 500 and the bottom surface 103 of the interconnection structure layer 100 may be reduced because the second die 400 are inserted into the cavity 509.

In the event that a semiconductor chip or a semiconductor package is mounted on a substrate using connectors such as solder electrodes or solder balls, a pitch of the solder electrodes may be proportional to a height of the solder electrodes. That is, if a height of the solder electrodes increases, an undesirable electrical path may be formed between the solder electrodes adjacent to each other during a solder reflow process. Thus, if a height of the solder electrodes increases, a distance between the solder electrodes has to increase to prevent electrical connection between the solder electrodes. This may lead to increase of a pitch of the solder electrodes. In such a case, the number of the solder electrodes disposed in a limited area may be reduced to make a difficulty in realizing high performance semiconductor packages.

The semiconductor package 10 may include a plurality of first connectors 330 disposed on the bottom surface 103 of the interconnection structure layer 100. The plurality of first connectors 330 may be conductive members having a ball shape, for example, solder bumps. The first connectors 330 may be disposed between the bottom surface 103 of the interconnection structure layer 100 and the top surface 503 of the package substrate 500 to have a pillar shape and to support the interconnection structure layer 100. Since the second die 400 are inserted into the cavity 509, a height H3 of the first connectors 330 may be reduced. If the height H3 of the first connectors 330 is reduced, a width W3 of the first connectors 330 may also be reduced. If the height H3 of the first connectors 330 increases, the width W3 of the first connectors 330 has to increase and a pitch of the first connectors 330 may also increase. However, according to an embodiment, the height H3 of the first connectors 330 may be reduced because the second die 400 are inserted into the cavity 509. Thus, a pitch P3 of the first connectors 330 may be reduced. That is, the first connectors 330 may be disposed to have a fine pitch. As a result, the number of the first connectors 330 (acting as I/O signal pins) disposed in a limited area may increase to realize a high performance semiconductor package. In other words, a width of the semiconductor package 10 may be relatively reduced to realize a semiconductor package having a reduced form factor.

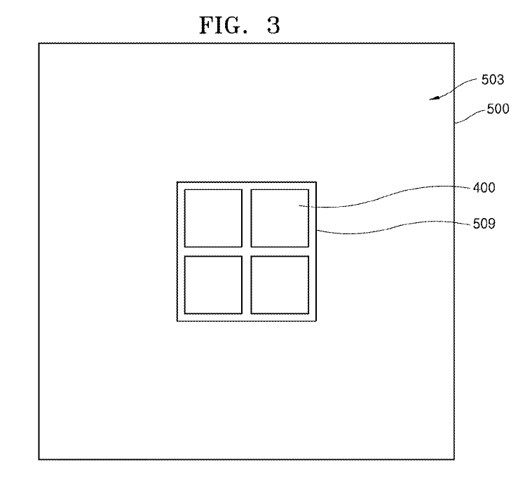

Referring to a plan view of FIG. 3, the plurality of second die 400 may be disposed to be adjacent to each other in the cavity 509. For example, four second die 400 may be two dimensionally arrayed in two rows and two columns on a bottom surface of the cavity 509 to have a matrix form. That is, the four second die 400 may be disposed to have a mosaic array. Since the second die 400 are disposed to be adjacent to each other, interconnection lines for electrically connecting the second die 400 to each other may be simply and easily disposed without any complexity.

Referring again to FIG. 1, the second die 400 may be electrically and mechanically connected to the bottom surface 103 of the interconnection structure layer 100 through second connectors 320. The second connectors 320 may be disposed on portions of the interconnection structure layer 100 overlapping with the second die 400. Since the second connectors 320 are directly combined with the second die 400, the second connectors 320 may be arrayed to have a width W1 and a pitch P1 which are respectively equal to a width and a pitch of signal I/O pads (not illustrated) of the second die 400. The width W1 and the pitch P1 of the second connectors 320 may be less than the width W3 and the pitch P3 of the first connectors 330, respectively. Since the width W1 of the second connectors 320 is less than the width W3 of the first connectors 330, a height H1 of the second connectors 320 may also be less than the height H3 of the first connectors 330. The second connectors 320 may be micro-bumps.

The first die 200 may be electrically and mechanically connected to the top surface 101 of the interconnection structure layer 100 through third connectors 310. The third connectors 310 may be disposed on portions of the interconnection structure layer 100 overlapping with the first die 200. Since the third connectors 310 are directly combined with the first die 200, the third connectors 310 may be arrayed to have a width W2 and a pitch P2 which are respectively equal to a width and a pitch of signal I/O pads (not illustrated) of the first die 200. The width W2 and the pitch P2 of the third connectors 310 may be less than the width W3 and the pitch P3 of the first connectors 330, respectively. Since the width W2 of the third connectors 310 is less than the width W3 of the first connectors 330, a height H2 of the third connectors 310 may also be less than the height H3 of the first connectors 330. The third connectors 310 may be micro-bumps. The width W2 and the pitch P2 of the third connectors 310 may be equal to or substantially equal to the width W1 and the pitch P1 of the second connectors 320, respectively.

The interconnection structure layer 100 may include first connection pads 143 disposed on the bottom surface 103 thereof to have a fine pitch and third connection pads 120 disposed on the top surface 101 thereof to have a fine pitch so that the second connectors 320 and the third connectors 310 arrayed to have the fine pitches P1 and P2 are mounted on the interconnection structure layer 100. The first connection pads 143 may be arrayed to have a pitch which is less than the pitch P3 of the first connectors 330. The first connection pads 143 may be arrayed to have a pitch which is substantially equal to the pitch P1 of the second connectors 320. The third connection pads 120 may be arrayed to have a pitch which is less than the pitch P3 of the first connectors 330. The third connection pads 120 may be arrayed to have a pitch which is substantially equal to the pitch P2 of the third connectors 310. A width and a pitch of the third connection pads 120 may be substantially equal to a width and a pitch of the first connection pads 143, respectively. A plurality of die pads (not illustrated) acting as signal I/O pads may be disposed on surfaces of the first and second die 200 and 400 to realize a high performance semiconductor package. If the number of the die pads disposed in a limited area increases, a pitch of the die pads may be reduced. If solder balls are disposed on the die pads and the pitch of the die pads is reduced, the adjacent solder balls may be electrically connected to each other to cause malfunction of the semiconductor package. Thus, a size (e.g., a width) of the solder balls has to be reduced to prevent the adjacent solder balls from being electrically connected to each other. The first connection pads 143 and the third connection pads 120 may be arrayed on surfaces of the interconnection structure layer 100 to have a pitch which is equal to a pitch of the die pads of the first and second die 200 and 400. That is, a pitch of the third connection pads 120 and the third connectors 310 may be set to be substantially equal to a pitch of the die pads (not illustrated) of the first die 200. Accordingly, a size of the third connectors 310 may depend on the pitch of the third connectors 310. A pitch of the first connection pads 143 and the second connectors 320 may be set to be substantially equal to a pitch of the die pads (not illustrated) of the first die 200, and a size of the second connectors 320 may be reduced in dependence on the pitch of the second connectors 320. The interconnection structure layer 100 may also include second connection pads 146 that are disposed to be adjacent to the first connection pads 143, and the second connection pads 146 may be arrayed to have a pitch which is greater than a pitch of the first connection pads 143. Since the first connectors 330 are mounted on the second connection pads 146, the second connection pads 146 may be disposed to have a pitch which is substantially equal to the pitch P3 of the first connectors 330. If entire portions of the second die 400 are completely inserted into the cavity 509 so that the height H3 of the first connectors 330 is substantially equal to the height H1 of the second connectors 320, a width and a pitch of the second connection pads 146 may be respectively equal to the width and the pitch of the first connection pads 143.

The interconnection structure layer 100 may include redistribution patterns 130 providing electrical connection paths for changing connection positions. The redistribution patterns 130 may include first redistribution patterns 134 substantially extending in a vertical direction to electrically connect the first die 200 to the second die 400, second redistribution patterns 135 substantially extending in a horizontal direction to electrically connect the second die 400 to some of the first connectors 330, and third redistribution patterns 132 substantially extending in a horizontal direction to electrically connect the first die 200 to the others of the first connectors 330.

Some pads 142 of the first connection pads 143 may be directly connected to first ends of the first redistribution patterns 134, and some pads 124 of the third connection pads 120 may be directly connected to second ends of the first redistribution patterns 134. The first redistribution patterns 134 may vertically penetrate a body of the interconnection structure layer 100. The pads 142 of the first connection pads 143 connected to the first ends of the first redistribution patterns 134 may be disposed to overlap with the pads 124 of the third connection pads 120 connected to the second ends of the first redistribution patterns 134, respectively.

The other pads 141 of the first connection pads 143 may be directly connected to first ends of the second redistribution patterns 135, and some pads 144 of the second connection pads 146 may be directly connected to second ends of the second redistribution patterns 135. Since the pads 144 of the second connection pads 146 and the pads 141 of the first connection pads 143 are all disposed on the bottom surface 103 of the interconnection structure layer 100, the second redistribution patterns 135 for electrically connecting the pads 144 of the second connection pads 146 to the pads 141 of the first connection pads 143 may be disposed to extend substantially in a horizontal direction parallel with the bottom surface 103 of the interconnection structure layer 100. The second redistribution patterns 135 may be disposed in a body of the interconnection structure layer 100. Alternatively, the second redistribution patterns 135 may be disposed on a surface (i.e., the bottom surface 103) of the interconnection structure layer 100 to reduce lengths thereof.

The other pads 122 of the third connection pads 120 may be directly connected to first ends of the third redistribution patterns 132, and the other pads 145 of the second connection pads 146 may be directly connected to second ends of the third redistribution patterns 132. Although the third redistribution patterns 132 penetrate a body of the interconnection structure layer 100 substantially in a vertical direction, the third redistribution patterns 132 may include horizontal portions that extend in a horizontal direction in order to connect the pads 122 of the third connection pads 120 to the pads 145 of the second connection pads 146 which are offset relative to the pads 122.

The first redistribution patterns 134 may provide electrical paths through which electrical signals between the first and second die 200 and 400 are transmitted, and the second redistribution patterns 135 may provide electrical paths through which electrical signals between the package substrate 500 and the second die 400 are transmitted. The third redistribution patterns 132 may provide electrical paths through which electrical signals between the first die 200 and the package substrate 500 are transmitted. The first, second and third redistribution patterns 134, 135 and 132 may be independent paths. The second redistribution patterns 135 may be used only to connect the package substrate 500 to the second die 400. Thus, the second redistribution patterns 135 may be used to apply signals for selectively testing only the second die 400 or for selectively repairing only the second die 400 to the second die 400.

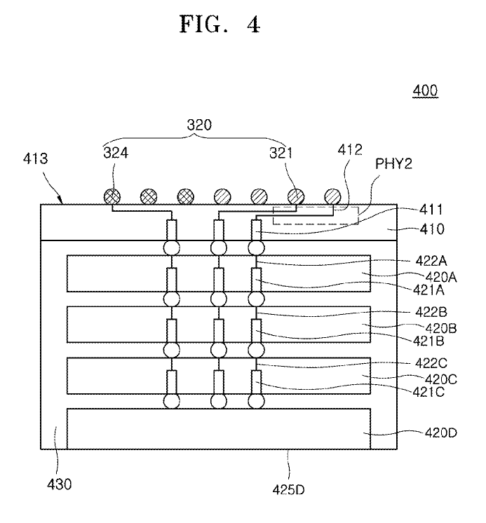

Referring to FIG. 4, each of the second die 400 may include a plurality of die 410, 420A, 420B, 420C and 420D which are vertically stacked. For example, each of the second die 400 may include a master die 410, a first slave die 420A, a second slave die 420B, a third slave die 420C and a fourth slave die 420D which are vertically stacked, and the plurality of die 410, 420A, 420B, 420C and 420D may be electrically connected to each other by through silicon vias (TSVs) 411, 421A, 421B and 421C and internal interconnectors 412, 422A, 422B and 422C. Sidewalls of the slave die 420A, 420B, 420C and 420D may be covered with a side molding part 430. A top surface 425D of an uppermost slave die (i.e., the fourth slave die 420D) may be exposed to improve a heat emission efficiency of the second die 400. The second connectors 320 may be disposed on a surface 413 of the master die 410. Some connectors 321 of the second connectors 320 may be disposed on the interface physical layer PHY2 for communicating with the first die 200, and other connectors 324 of the second connectors 320 may be disposed on a portion of the surface 413 for communicating with the package substrate 500. Each second die 400 including the stacked die 410, 420A, 420B, 420C and 420D may be a high performance memory device such as an HBM chip.

Referring again to FIG. 1, the semiconductor package 10 may further include a molding part 250 that surrounds and protects the first die 200. The molding part 250 may surround sidewalls of the first die 200 to expose a top surface 203 of the first die 200. A heat emission structure (not illustrated) may be disposed on the top surface 203 of the first die 200. The heat emission structure, for example, a heat spreader may be attached to the top surface 203 of the first die 200 using a thermal interface material (TIM).

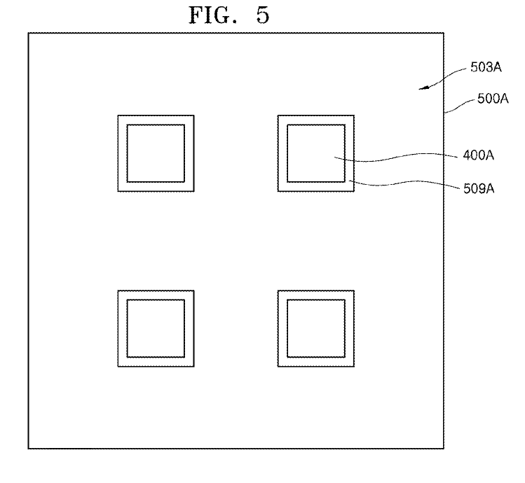

Referring to FIG. 1, the cavity 509 may be located at a central portion of the package substrate 500, and the second die 400 may be inserted into the cavity 509 to overlap with a central portion of the first die 200. Referring to FIG. 5, cavities 509A may be provided in a package substrate 500A to be adjacent to four corners 503A of the package substrate 500A, respectively. In such a case, the cavities 509A may be located to be point symmetric or substantially point symmetric with respect to a central point of the package substrate 500A. Thus, second die 400A (corresponding to the second die 400 of FIG. 1) inserted into respective ones of the cavities 509A may also be disposed to be adjacent to the four corners of the package substrate 500A, respectively, and the interface physical layers PHY2 of the second die 400A may overlap with the first die 200. In such a case, the second die 400A may be disposed to be spaced apart from each other and may also be point symmetric or substantially point symmetric with respect to a central point of the package substrate 500A.

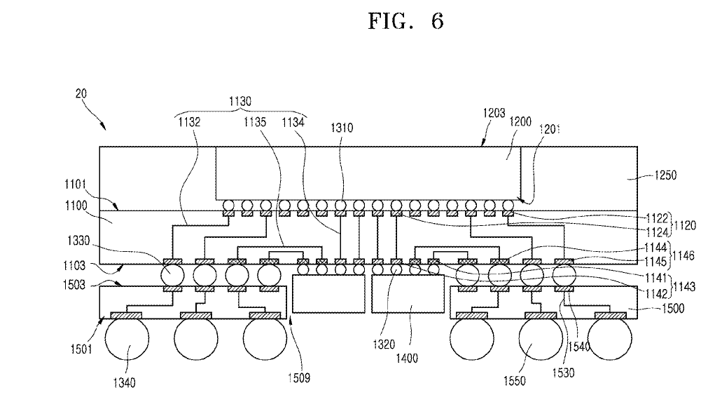

FIG. 6 is a cross-sectional view illustrating a semiconductor package 20 according to an embodiment. Some elements illustrated in FIG. 6 may be substantially the same as some elements illustrated in FIG. 1.

Referring to FIG. 6, the semiconductor package 20 may be configured to include an interconnection structure layer 1100, a first die 1200 disposed on a top surface 1101 of the interconnection structure layer 1100, and second die 1400 disposed on a bottom surface 1103 of the interconnection structure layer 1100 opposite to the first die 1200. The semiconductor package 20 may include a package substrate 1500 which is electrically and mechanically connected to the first die 1200, the interconnection structure layer 1100 and the second die 1400. The package substrate 1500 may have a top surface 1503 on which the first and second dies 1200 and 1400 and the interconnection structure layer 1100 are disposed. External connection terminals 1340 may be disposed on a bottom surface 1501 of the package substrate 1500 opposite to the first and second dies 1200 and 1400 and the interconnection structure layer 1100.

The package substrate 1500 may include package interconnection structures 1530+1540+1550 acting as circuit interconnection lines for electrically connecting the first and second die 1200 and 1400 to an external device. The package interconnection structures 1530+1540+1550 may include first package interconnection pads 1540 that are disposed on the top surface 1503 of the package substrate 1500 and are electrically connected to the first and second die 1200 and 1400. In addition, the package interconnection structures 1530+1540+1550 may include second package interconnection pads 1550 combined with the external connection terminals 1340 and package interconnection lines 1530 for electrically connecting the first package interconnection pads 1540 to the second package interconnection pads 1550. A cavity 1509 may be provided in the package substrate 1500. The cavity 1509 may penetrate a portion of a body of the package substrate 1500 to have a through hole shape. The second die 1400 may be at least partially inserted into the cavity 1509.

The semiconductor package 20 may include a plurality of first connectors 1330 disposed on the bottom surface 1103 of the interconnection structure layer 1100. The second die 1400 may be electrically and mechanically connected to the bottom surface 1103 of the interconnection structure layer 1100 through second connectors 1320. The first die 1200 may be electrically and mechanically connected to the top surface 1101 of the interconnection structure layer 1100 through third connectors 1310.

The interconnection structure layer 1100 may include first connection pads 1143 disposed on the bottom surface 1103 thereof to have a fine pitch and third connection pads 1120 disposed on the top surface 1101 thereof to have a fine pitch. The interconnection structure layer 1100 may also include second connection pads 1146 that are disposed to be adjacent to the first connection pads 1143, and the second connection pads 1146 may be arrayed to have a pitch which is greater than a pitch of the first connection pads 1143.

The interconnection structure layer 1100 may include redistribution patterns 1130 providing electrical connection paths for changing connection positions. The redistribution patterns 1130 may include first redistribution patterns 1134 substantially extending in a vertical direction to electrically connect the first die 1200 to the second die 1400, second redistribution patterns 1135 substantially extending in a horizontal direction to electrically connect the second die 1400 to some of the first connectors 1330, and third redistribution patterns 1132 substantially extending in a horizontal direction to electrically connect the first die 1200 to the others of the first connectors 1330.

Some pads 1142 of the first connection pads 1143 may be directly connected to first ends of the first redistribution patterns 1134, and some pads 1124 of the third connection pads 1120 may be directly connected to second ends of the first redistribution patterns 1134. The other pads 1141 of the first connection pads 1143 may be directly connected to first ends of the second redistribution patterns 1135, and some pads 1144 of the second connection pads 1146 may be directly connected to second ends of the second redistribution patterns 1135. The other pads 1122 of the third connection pads 1120 may be directly connected to first ends of the third redistribution patterns 1132, and the other pads 1145 of the second connection pads 1146 may be directly connected to second ends of the third redistribution patterns 1132.

The semiconductor package 20 may further include a molding part 1250 that surrounds and protects the first die 1200. The molding part 1250 may surround sidewalls of the first die 1200 to expose a top surface 1203 of the first die 1200.

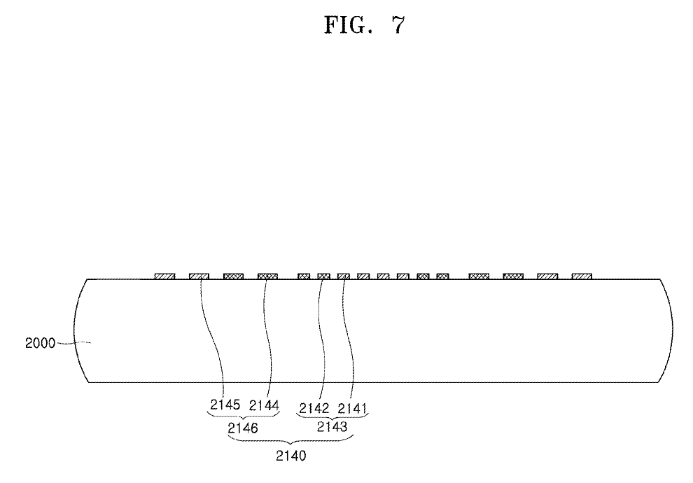

FIGS. 7 to 16 are cross-sectional views illustrating a method of manufacturing a semiconductor package according to an embodiment. FIGS. 7 to 16 illustrate a method of manufacturing the semiconductor package 10 illustrated in FIG. 1. Some elements illustrated in FIGS. 7 to 16 may be substantially the same as some elements described with reference to FIG. 1.

FIG. 7 illustrates a step of forming an array of conductive pads 2140 on a dummy wafer 2000. The conductive pads 2140 may include first connection pads 2143 and second connection pads 2146. The dummy wafer 2000 may act as a supporter that is used in formation of the interconnection structure layer (100 of FIG. 1). The dummy wafer 2000 may be a bare silicon wafer. The dummy wafer 2000 may be introduced to form a stack structure comprised of conductive patterns and dielectric layers constituting the interconnection structure layer (100 of FIG. 1). Thus, in some embodiments, the dummy wafer 2000 may be a wafer which is different from a bare silicon wafer. For example, the dummy wafer 2000 may be a sapphire wafer, a silicon-on-insulator (SOI) wafer, an insulation material wafer, or a dielectric material wafer. If a bare silicon wafer is employed as the dummy wafer 2000, semiconductor processes may be applied to the dummy wafer 2000 to form the interconnection structure layer 100. Forming the interconnection structure layer 100 may include forming redistribution lines on the dummy wafer 2000. The following processes may include wafer processing techniques. In some embodiments, a sequence of the following processes or a shape of patterns may be modified or changed to simplify the process for forming the redistribution lines. Since the dummy wafer 2000 has a flat surface, the conductive pads 2140 may be formed to have a fine pitch and a size of the conductive pads 2140 may be accurately controlled.

Specifically, a conductive layer may be formed on the dummy wafer 2000, and the conductive layer may be patterned to form the first connection pads 2143 and the second connection pads 2146. Some pads 2142 of the first connection pads 2143 may be formed on a portion of the dummy wafer 2000 to be directly connected to first ends of the first redistribution patterns (134 of FIG. 1), and the other pads 2141 of the first connection pads 2143 may be formed on another portion of the dummy wafer 2000 to be directly connected to first ends of the second redistribution patterns (135 of FIG. 1). Some pads 2144 of the second connection pads 2146 may be formed on another portion of the dummy wafer 2000 to be directly connected to second ends of the second redistribution patterns (135 of FIG. 1), and the other pads 2145 of the second connection pads 2146 may be formed on another portion of the dummy wafer 2000 to be directly connected to first ends of the third redistribution patterns (132 of FIG. 1).

Even though a pitch of the first connection pads 2143 is different from a pitch of the second connection pads 2146, the first and second connection pads 2143 and 2146 may be formed to have a finer pitch as compared with circuit interconnections formed on a printed circuit board (PCB). This is because a surface flatness of the dummy wafer 2000 is more excellent than a surface flatness of the PCB.

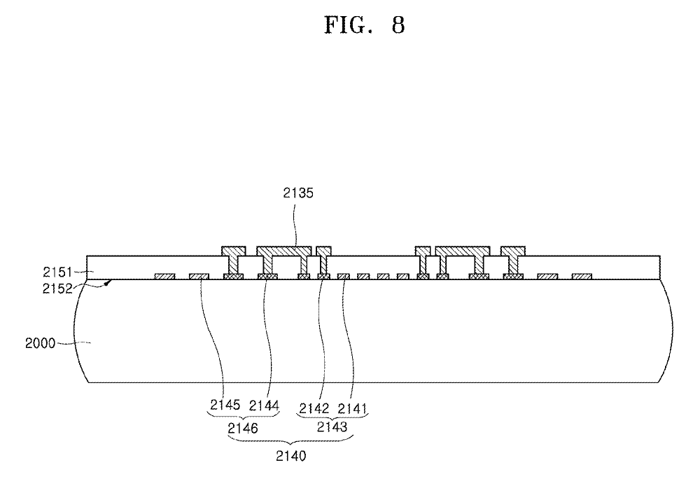

Referring to FIG. 8, a first dielectric layer 2151 may be formed on the dummy wafer 2000 to electrically insulate the first and second connection pads 2143 and 2146 from each other. The first dielectric layer 2151 may be formed to include at least one of various dielectric layers. For example, the first dielectric layer 2151 may be formed to include an insulation layer used as an interlayer dielectric layer, an insulation layer used as an inter-metal dielectric layer, a polymer layer such as a polyimide layer, a silicon oxide layer, a silicon nitride layer, or the like. The first dielectric layer 2151 may be formed using a lamination process, a deposition process or a coating process.

First conductive patterns 2135 acting as the second redistribution patterns (135 of FIG. 1) may be formed on the first dielectric layer 2151 to electrically connect the pads 2142 of the first connection pads 2143 to the pads 2144 of the second connection pads 2146. First ends of the first conductive patterns 2135 may extend into the first dielectric layer 2151 to contact the pads 2142 of the first connection pads 2143, and second ends of the first conductive patterns 2135 may extend into the first dielectric layer 2151 to contact the pads 2144 of the second connection pads 2146.

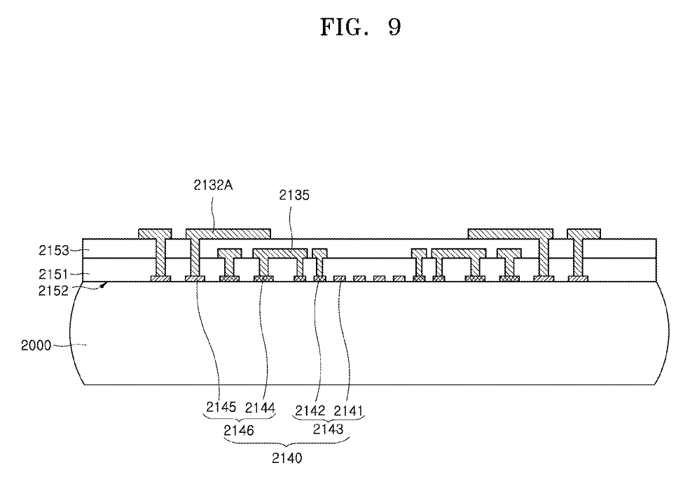

Referring to FIG. 9, a second dielectric layer 2153 may be formed on the first dielectric layer 2151 to electrically insulate the first conductive patterns 2135 from each other. The second dielectric layer 2153 may be formed to include at least one of various dielectric layers. For example, the second dielectric layer 2153 may be formed to include an insulation layer used as an interlayer dielectric layer, an insulation layer used as an inter-metal dielectric layer, a polymer layer such as a polyimide layer, a silicon oxide layer, a silicon nitride layer, or the like. The second dielectric layer 2153 may be formed using a lamination process, a deposition process or a coating process.

Second conductive patterns 2132A corresponding to portions of the third redistribution patterns (132 of FIG. 1) may be formed on the second dielectric layer 2153. First ends of the second conductive patterns 2132A may extend into the first and second dielectric layers 2151 and 2153 to contact the other pads 2145 of the second connection pads 2146. Accordingly, the first ends of the second conductive patterns 2132A may have a via shape.

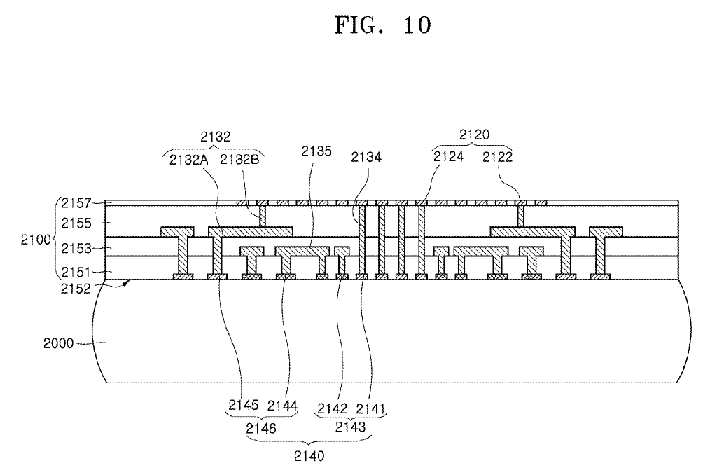

Referring to FIG. 10, a third dielectric layer 2155 may be formed on the second dielectric layer 2153 to electrically insulate the second conductive patterns 2132A from each other. The third dielectric layer 2155 may be formed to include at least one of various dielectric layers. Third conductive patterns 2134 corresponding to the first redistribution patterns (134 of FIG. 1) may be formed to vertically penetrate the first to third dielectric layers 2151, 2153 and 2155. First ends of the third conductive patterns 2134 may be connected to the other pads 2141 of the first connection pads 2143, respectively. Fourth conductive patterns 2132B may be formed to vertically penetrate the third dielectric layer 2155. First ends of the fourth conductive patterns 2132B may be connected to the second conductive patterns 2132A. The second conductive patterns 2132A and the fourth conductive patterns 2132B may constitute redistribution patterns 2132 corresponding to the third redistribution patterns (132 of FIG. 1).

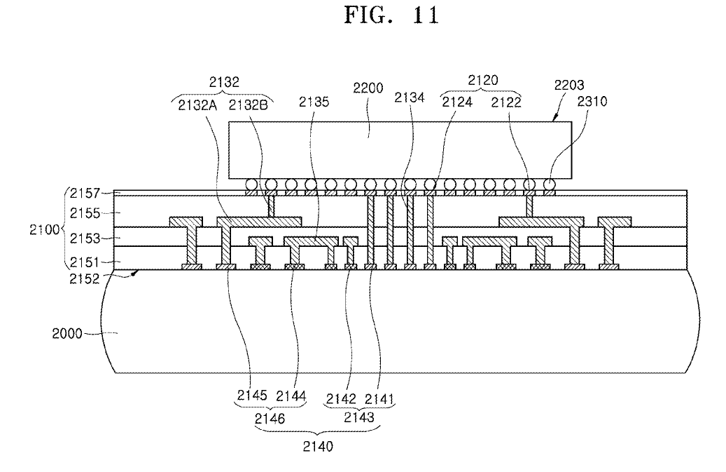

Referring to FIG. 11, third connection pads 2120 may be formed on the third dielectric layer 2155 to overlap with the third conductive patterns 2134 and the fourth conductive patterns 2132B. That is, the third connection pads 2120 may be formed to be electrically connected to the conductive patterns 2134 and the fourth conductive patterns 2132B. Some pads 2124 of the third connection pads 2120 may be connected to the third conductive patterns 2134 corresponding to the first redistribution patterns (134 of FIG. 1), and the other pads 2122 of the third connection pads 2120 may be connected to the fourth conductive patterns 2132B of the redistribution patterns 2132 corresponding to the third redistribution patterns (132 of FIG. 1). Subsequently, a fourth dielectric layer 2157 may be formed on the third dielectric layer 2155 to electrically insulate the third connection pads 2120 from each other. The first to fourth dielectric layers 2151, 2153, 2155 and 2157 may constitute a body of an interconnection structure layer 2100.

A first die 2200 may be mounted on the interconnection structure layer 2100. The first die 2200 may be connected to the third connection pads 2120 through third connectors 2310.

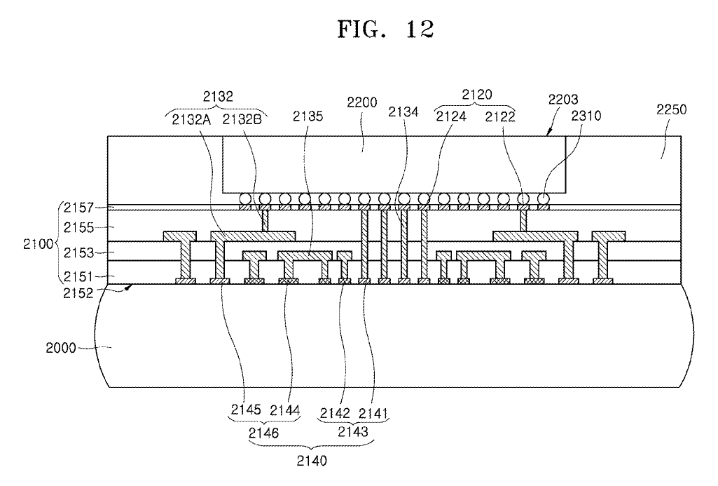

Referring to FIG. 12, a molding part 2250 may be formed to protect the first die 2200. The molding part 2250 may be formed of a molding compound material using a molding process to cover sidewalls of the first die 2200 and to expose a top surface 2203 of the first die 2200.

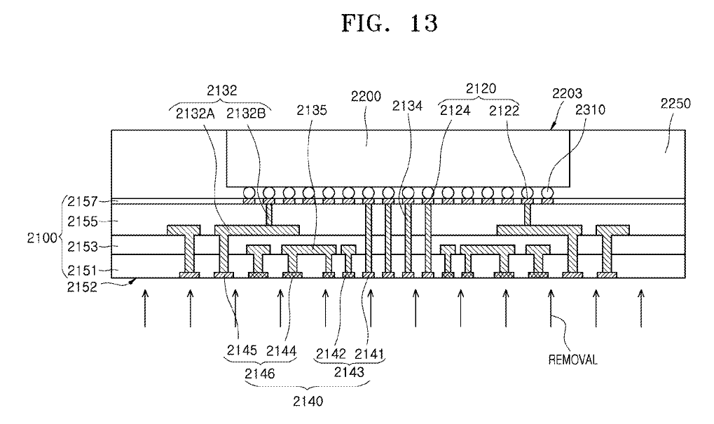

Referring to FIG. 13, a backside surface of the dummy wafer (2000 of FIG. 12) may be recessed to expose a surface 2152 of the interconnection structure layer 2100. Recessing the backside surface of the dummy wafer (2000 of FIG. 12) may include removing the dummy wafer (2000 of FIG. 12) from the interconnection structure layer 2100. The dummy wafer (2000 of FIG. 12) may be removed by applying a back grinding process to a backside surface of the dummy wafer 2000 opposite to the interconnection structure layer 2100 and by etching back the ground dummy wafer until the surface 2152 of the interconnection structure layer 2100 is exposed. The interconnection structure layer 2100 may have an insufficient thickness to maintain its original shape. However, the molding part 2250 and the first die 2200 may be formed before the dummy wafer (2000 of FIG. 12) is removed. Thus, even though the dummy wafer (2000 of FIG. 12) is removed, the interconnection structure layer 2100 may be supported by the molding part 2250 and the first die 2200 to maintain its original flat shape. Accordingly, no additional carriers or no additional supporters for supporting the interconnection structure layer 2100 may be required.

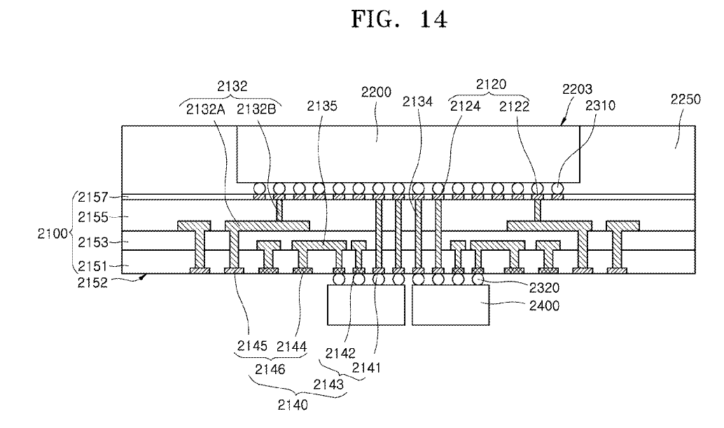

Referring to FIG. 14, second die 2400 may be mounted on the bottom surface 2152 of the interconnection structure layer 2100. The second die 2400 may be connected to the first connection pads 2143 through second connectors 2320.

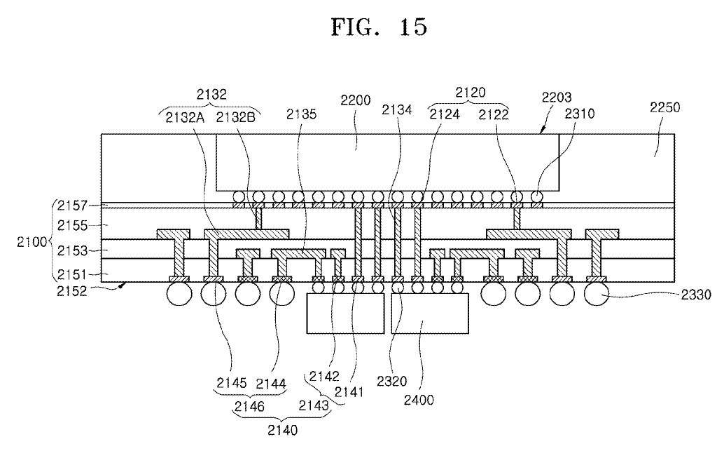

Referring to FIG. 15, a plurality of first connectors 2330 may be attached to the second connection pads 2146 disposed on the bottom surface 2152 of the interconnection structure layer 2100. The first connectors 2330 may be attached to the second connection pads 2146 using a ball mounting process.

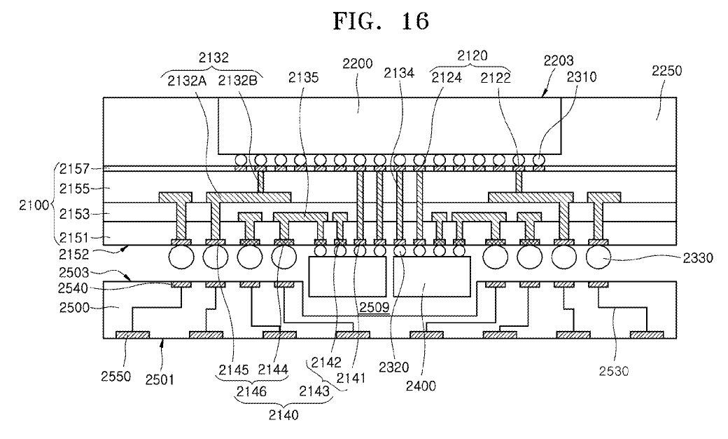

Referring to FIG. 16, a package substrate 2500 may be electrically connected to the first connectors 2330. The package substrate 2500 may include package interconnection structures 2530+2540+2550 acting as circuit interconnection lines for electrically connecting the first and second die 2200 and 2400 to an external device. The package substrate 2500 may include a dielectric body for electrically insulating the package interconnection structures 2530+2540+2550 from each other. The package interconnection structures 2530+2540+2550 may include first package interconnection pads 2540 that are disposed on a top surface 2503 of the package substrate 2500 and are electrically connected to the first and second die 2200 and 2400. In addition, the package interconnection structures 2530+2540+2550 may include second package interconnection pads 2550 combined with external connection terminals (340 of FIG. 1) attached to a bottom surface 2501 of the package substrate 2500 and package interconnection lines 2530 for electrically connecting the first package interconnection pads 2540 to the second package interconnection pads 2550. A portion of the top surface 2503 of the package substrate 2500 may be recessed to provide a cavity 2509 located in the package substrate 2500. The second die 2400 may be at least partially inserted into the cavity 2509.

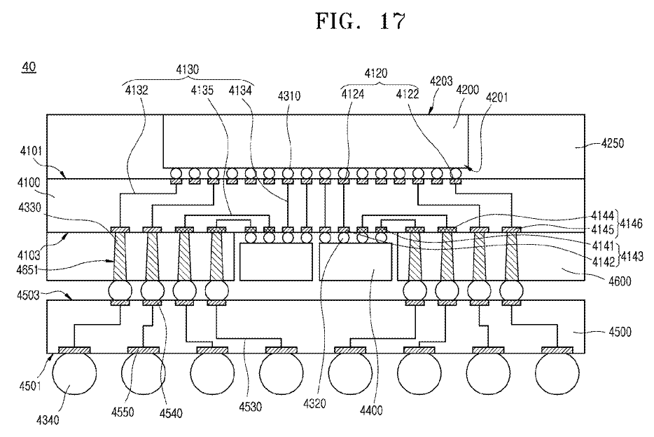

FIG. 17 is a cross-sectional view illustrating a semiconductor package 40 according to yet another embodiment. Some elements illustrated in FIG. 17 may be substantially the same as some elements illustrated in FIG. 1 or 6.

Referring to FIG. 17, the semiconductor package 40 may be configured to include an interconnection structure layer 4100, a first die 4200 disposed on a top surface 4101 of the interconnection structure layer 4100, and second die 4400 disposed on a bottom surface 4103 of the interconnection structure layer 4100 opposite to the first die 4200. The semiconductor package 40 may include a package substrate 4500 which is electrically and mechanically connected to the first die 4200, the interconnection structure layer 4100 and the second die 4400. The semiconductor package 40 may further include a first molding part 4250 that surrounds sidewalls of the first die 4200 to expose a top surface 4203 of the first die 4200.

The package substrate 4500 may have a top surface 4503 on which the second dies 4400 are disposed. External connection terminals 4340 may be disposed on a bottom surface 4501 of the package substrate 4500 opposite to the second dies 4400. The package substrate 4500 may include package interconnection structures 4530+4540+4550 acting as circuit interconnection lines for electrically connecting the first and second die 4200 and 4400 to an external device. The package interconnection structures 4530+4540+4550 may include first package interconnection pads 4540 that are disposed on the top surface 4503 of the package substrate 4500 and are electrically connected to the first and second die 4200 and 4400. In addition, the package interconnection structures 4530+4540+4550 may include second package interconnection pads 4550 combined with the external connection terminals 4340 disposed on the bottom surface 4501 of the package substrate 4500 and package interconnection lines 4530 for electrically connecting the first package interconnection pads 4540 to the second package interconnection pads 4550.

The semiconductor package 40 may include a plurality of through mold vias 4650 which are connected to the bottom surface 4103 of the interconnection structure layer 4100. The semiconductor package 40 may further include a second molding part 4600 surrounding sidewalls of the through mold vias 4650. The second molding part 4600 may cover a portion of the bottom surface 4103 of the interconnection structure layer 4100, which is adjacent to the second die 4400 and may open another portion of the bottom surface 4103 of the interconnection structure layer 4100 where the second die 4400 are located.

The second molding part 4600 may be formed of a molding compound material such as an epoxy molding compound (EMC) material using a molding process. The second molding part 4600 may be located to face the first molding part 4250 with the interconnection structure layer 4100 disposed between the first and second molding parts 4250 and 4600. An EMC material of the first molding part 4250 may have a coefficient of thermal expansion which is quite different from a coefficient of thermal expansion of a silicon substrate included in the first die 4200 or the second die 4400. Thus, the first molding part 4250 may cause warpage or crack of the semiconductor package 40 if the second molding part 4600 is absent. That is, since the second molding part 4600 is disposed on the bottom surface 4103 of the interconnection structure layer 4100 opposite to the first molding part 4250, the second molding part 4600 may compensate for the warpage or crack of the semiconductor package 40 due to the coefficient of thermal expansion of the first molding part 4250 to prevent deformation of the semiconductor package 40. The through mold vias 4650 may be comprised of a conductive material filling through holes 4651 that vertically penetrate the second molding part 4600. The through mold vias 4650 may provide paths for electrically connecting the package substrate 4500 to the interconnection structure layer 4100, like the first connectors 330 illustrated in FIG. 1. That is, the through mold vias 4650 may have substantially the same or similar function as the first connectors 330 illustrated in FIG. 1.

The second die 4400 may be electrically and mechanically connected to the bottom surface 4103 of the interconnection structure layer 4100 through first connectors 4320. The first connectors 4320 may correspond to the second connectors 320 of FIG. 2. The first die 4200 may be electrically and mechanically connected to the top surface 4101 of the interconnection structure layer 4100 through second connectors 4310.

The interconnection structure layer 4100 may include first connection pads 4143 disposed on the bottom surface 4103 thereof to have a fine pitch and third connection pads 4120 disposed on the top surface 4101 thereof to have a fine pitch. The interconnection structure layer 4100 may also include second connection pads 4146 that are disposed to be adjacent to the first connection pads 4143, and the second connection pads 4146 may be arrayed to have a pitch which is greater than a pitch of the first connection pads 4143.

The interconnection structure layer 4100 may include redistribution patterns 4130 providing electrical connection paths for changing connection positions. The redistribution patterns 4130 may include first redistribution patterns 4134 substantially extending in a vertical direction to electrically connect the first die 4200 to the second die 4400, second redistribution patterns 4135 substantially extending in a horizontal direction to electrically connect the second die 4400 to some of the through mold vias 4650, and third redistribution patterns 4132 electrically connecting the first die 4200 to the others of the through mold vias 4650.

Some pads 4142 of the first connection pads 4143 may be directly connected to first ends of the first redistribution patterns 4134, and some pads 4124 of the third connection pads 4120 may be directly connected to second ends of the first redistribution patterns 4134. The other pads 4141 of the first connection pads 4143 may be directly connected to first ends of the second redistribution patterns 4135, and some pads 4144 of the second connection pads 4146 may be directly connected to second ends of the second redistribution patterns 4135. The other pads 4122 of the third connection pads 4120 may be directly connected to first ends of the third redistribution patterns 4132, and the other pads 4145 of the second connection pads 4146 may be directly connected to second ends of the third redistribution patterns 4132.

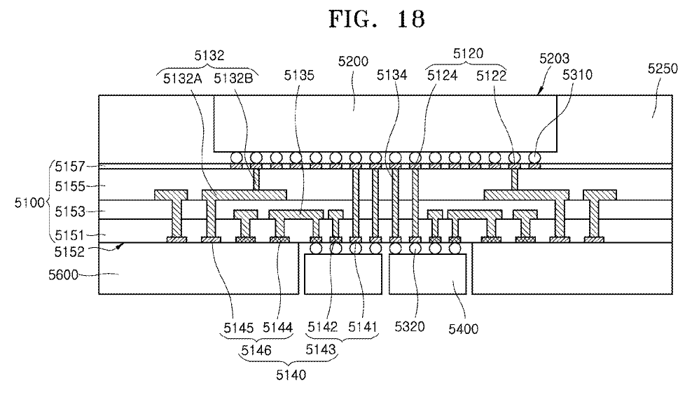

FIGS. 18 to 22 are cross-sectional views illustrating a method of manufacturing a semiconductor package according to another embodiment. FIGS. 18 to 22 illustrate a method of manufacturing the semiconductor package 40 illustrated in FIG. 17. Some elements illustrated in FIGS. 18 to 22 may be substantially the same as some elements described with reference to FIG. 1 or 17 or some elements described with reference to FIGS. 7 to 16.

FIG. 18 illustrates a step of forming an array of conductive pads 5140 on the dummy wafer (2000 of FIG. 7). The conductive pads 5140 may be formed to include first connection pads 5143 and second connection pads 5146. Specifically, as described with reference to FIG. 7, a conductive layer may be formed on the dummy wafer 2000, and the conductive layer may be patterned to form the first connection pads 5143 and the second connection pads 5146. Some pads 5142 of the first connection pads 5143 may be formed on a portion of the dummy wafer to be directly connected to first ends of the first redistribution patterns (134 of FIG. 1), and the other pads 5141 of the first connection pads 5143 may be formed on another portion of the dummy wafer to be directly connected to first ends of the second redistribution patterns (135 of FIG. 1). Some pads 5144 of the second connection pads 5146 may be formed on another portion of the dummy wafer to be directly connected to second ends of the second redistribution patterns (135 of FIG. 1), and the other pads 5145 of the second connection pads 5146 may be formed on another portion of the dummy wafer to be directly connected to first ends of the third redistribution patterns (132 of FIG. 1).

As described with reference to FIG. 8, a first dielectric layer 5151 may be formed on the dummy wafer to electrically insulate the first and second connection pads 5143 and 5146 from each other. First conductive patterns 5135 acting as the second redistribution patterns (135 of FIG. 1) may be formed on the first dielectric layer 5151 to electrically connect the pads 5142 of the first connection pads 5143 to the pads 5144 of the second connection pads 5146. First ends of the first conductive patterns 5135 may extend into the first dielectric layer 5151 to contact the pads 5142 of the first connection pads 5143, and second ends of the first conductive patterns 5135 may extend into the first dielectric layer 5151 to contact the pads 5144 of the second connection pads 5146.

As described with reference to FIG. 9, a second dielectric layer 5153 may be formed on the first dielectric layer 5151 to electrically insulate the first conductive patterns 5135 from each other. Second conductive patterns 5132A corresponding to portions of the third redistribution patterns (132 of FIG. 1) may be formed on the second dielectric layer 5153. First ends of the second conductive patterns 5132A may extend into the first and second dielectric layers 5151 and 5153 to contact the other pads 5145 of the second connection pads 5146. Accordingly, the first ends of the second conductive patterns 5132A may have a via shape.

As described with reference to FIG. 10, a third dielectric layer 5155 may be formed on the second dielectric layer 5153 to electrically insulate the second conductive patterns 5132A from each other. The third dielectric layer 2155 may be formed to include at least one of various dielectric layers. Third conductive patterns 5134 corresponding to the first redistribution patterns (134 of FIG. 1) may be formed to vertically penetrate the first to third dielectric layers 5151, 5153 and 5155. First ends of the third conductive patterns 5134 may be connected to the other pads 5141 of the first connection pads 5143, respectively. Fourth conductive patterns 5132B may be formed to vertically penetrate the third dielectric layer 5155. First ends of the fourth conductive patterns 5132B may be connected to the second conductive patterns 5132A. The second conductive patterns 5132A and the fourth conductive patterns 5132B may constitute redistribution patterns 5132 corresponding to the third redistribution patterns (132 of FIG. 1).

As described with reference to FIG. 11, third connection pads 5120 may be formed on the third dielectric layer 5155 to overlap with the third conductive patterns 5134 and the fourth conductive patterns 5132B. That is, the third connection pads 5120 may be formed to be electrically connected to the conductive patterns 5134 and the fourth conductive patterns 5132B. Some pads 5124 of the third connection pads 5120 may be connected to the third conductive patterns 5134 corresponding to the first redistribution patterns (134 of FIG. 1), and the other pads 5122 of the third connection pads 5120 may be connected to the fourth conductive patterns 5132B of the redistribution patterns 5132 corresponding to the third redistribution patterns (132 of FIG. 1). Subsequently, a fourth dielectric layer 5157 may be formed on the third dielectric layer 5155 to electrically insulate the third connection pads 5120 from each other. The first to fourth dielectric layers 5151, 5153, 5155 and 5157 may constitute a body of an interconnection structure layer 5100.

A first die 5200 may be mounted on the interconnection structure layer 5100. The first die 5200 may be connected to the third connection pads 5120 through second connectors 5310.

As described with reference to FIG. 12, a molding part 5250 may be formed to protect the first die 5200. The molding part 5250 may be formed of a molding compound material using a molding process to cover sidewalls of the first die 5200 and to expose a top surface 5203 of the first die 5200.

As described with reference to FIG. 13, a backside surface of the dummy wafer (2000 of FIG. 12) may be recessed to expose a surface 5152 of the interconnection structure layer 5100.

As described with reference to FIG. 14, second die 5400 may be mounted on the bottom surface 5152 of the interconnection structure layer 5100. The second die 5400 may be connected to the first connection pads 5143 through first connectors 5320.

Referring again to FIG. 18, a second molding part 5600 may be formed on the bottom surface 5152 of the interconnection structure layer 5100 to expose the second die 5400. The second molding part 5600 may be formed by partially molding a molding compound material using a molding process. In such a case, the molding process may be controlled so that the second molding part 5600 is formed to be spaced apart from the second die 5400.

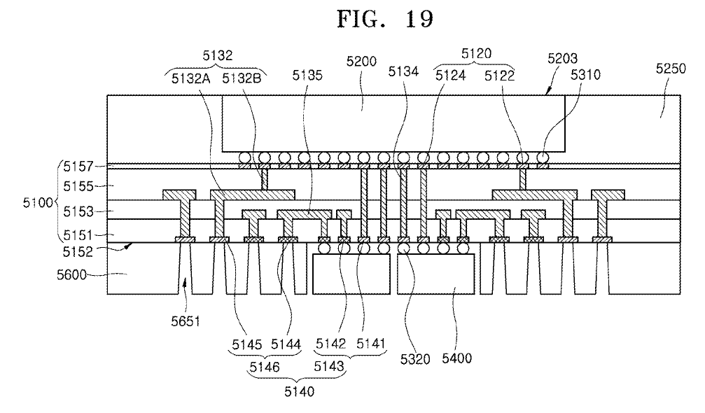

Referring to FIG. 19, the second molding part 5600 may be patterned to form through holes 5651 that penetrate the second molding part 5600 to expose the second connection pads 5146.

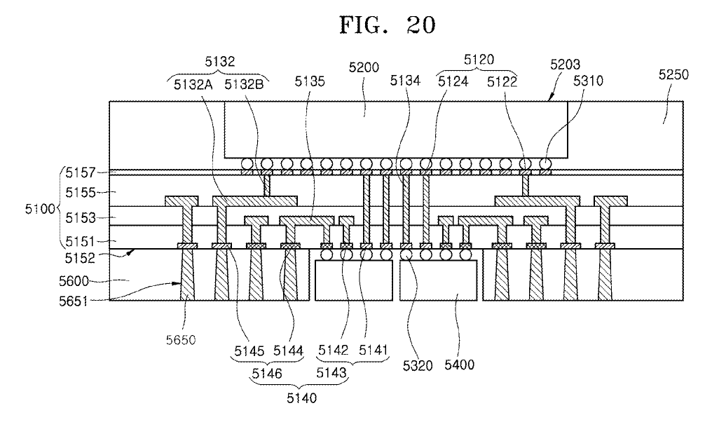

Referring to FIG. 20, the through holes 5651 may be filled with a conductive material to form through mold vias (TMVs) 5650.

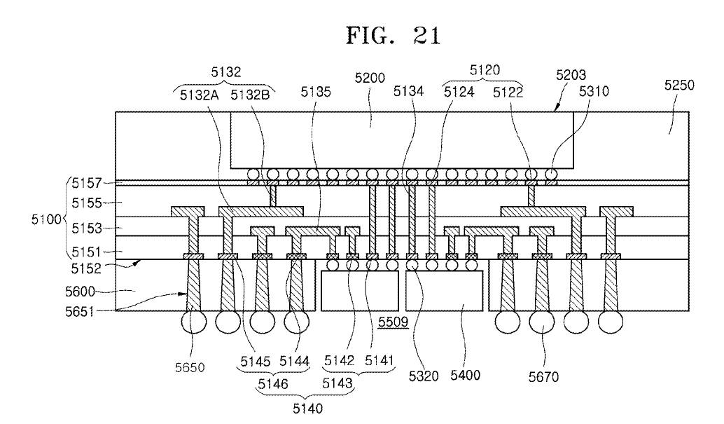

Referring to FIG. 21, third connectors 5670 may be formed on the through mold vias (TMVs) 5650, respectively. The third connectors 5670 may be formed of solder balls using a ball drop process.

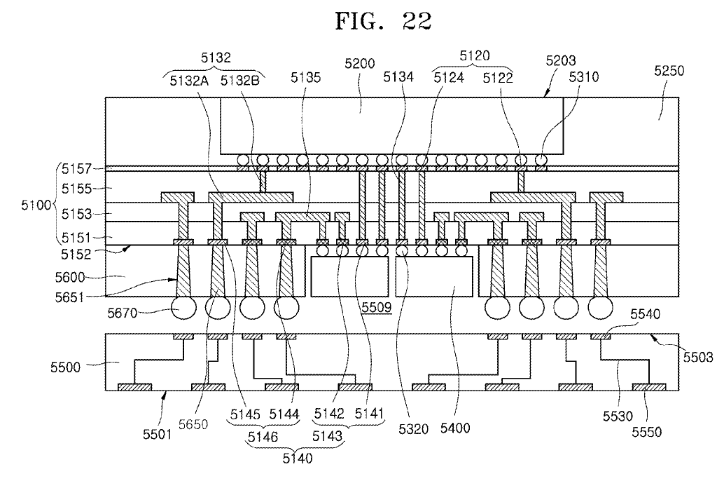

Referring to FIG. 22, a package substrate 5500 may be attached to the second molding part 5600 to be electrically connected to the third connectors 5670. The package substrate 5500 may include package interconnection structures 5530+5540+5550 acting as circuit interconnection lines for electrically connecting the first and second die 5200 and 5400 to an external device. The package substrate 5500 may include a dielectric body for electrically insulating the package interconnection structures 5530+5540+5550 from each other. The package interconnection structures 5530+5540+5550 may include first package interconnection pads 5540 that are disposed on a top surface 5503 of the package substrate 5500 and are electrically connected to the first and second die 5200 and 5400. In addition, the package interconnection structures 5530+5540+5550 may include second package interconnection pads 5550 combined with external connection terminals (4340 of FIG. 17) attached to a bottom surface 5501 of the package substrate 5500 and package interconnection lines 5530 for electrically connecting the first package interconnection pads 5540 to the second package interconnection pads 5550.

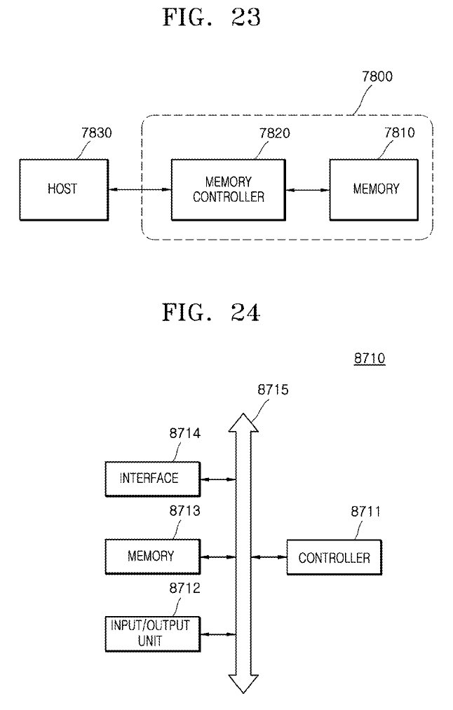

FIG. 23 is a block diagram illustrating an electronic system including a memory card 7800 including at least one semiconductor package according to an embodiment. The memory card 7800 includes a memory 7810 such as a nonvolatile memory device, and a memory controller 7820. The memory 7810 and the memory controller 7820 may store data or read stored data. The memory 7810 and/or the memory controller 7820 may include one or more semiconductor die disposed in a semiconductor package according to an embodiment.

The memory 7810 may include a nonvolatile memory device to which the technology of the embodiments of the present disclosure is applied. The memory controller 7820 may control the memory 7810 such that stored data is read out or data is stored in response to a read/write request from a host 7830.

FIG. 24 is a block diagram illustrating an electronic system 8710 including at least one package according to an embodiment. The electronic system 8710 may include a controller 8711, an input/output device 8712, and a memory 8713. The controller 8711, the input/output device 8712 and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 or the memory 8713 may include one or more of the semiconductor packages according to embodiments of the present disclosure. The input/output device 8712 may include at least one selected among a keypad, a keyboard, a display device, a touchscreen and so forth. The memory 8713 is a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

If the electronic system 8710 is an equipment capable of performing wireless communication, the electronic system 8710 may be used in a communication system such as of CDMA (code division multiple access), GSM (global system for mobile communications), NADC (north American digital cellular), E-TDMA (enhanced-time division multiple access), WCDAM (wideband code division multiple access), CDMA2000, LTE (long term evolution) and Wibro (wireless broadband Internet).

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A semiconductor package comprising:
a first die;
an interconnection structure layer electrically connected to the first die;
a plurality of first connectors disposed on the interconnection structure layer;
at least one second die disposed to overlap with a portion of the first die; and
a package substrate electrically connected to the plurality of first connectors,
wherein the package substrate has a cavity therein and the at least one second die is at least partially disposed in the cavity, and
wherein the interconnection structure layer includes:
first redistribution patterns extending substantially in a vertical direction to electrically connect the first die to the at least one second die;
second redistribution patterns extending substantially in a horizontal direction to electrically connect the at least one second die to some of the plurality of first connectors; and
third redistribution patterns electrically connecting the first die to the others of the plurality of first connectors.

2. The semiconductor package of claim 1,
wherein the first and second dies are disposed on the opposite surfaces of the interconnection structure layer.

3. The semiconductor package of claim 1, wherein the at least one second die and the plurality of first connectors are disposed on one surface of the interconnection structure layer.

4. The semiconductor package of claim 1, further comprising:
a plurality of second connectors disposed between the at least one second die and the interconnection structure layer to electrically connect the at least one second die to the interconnection structure layer, wherein the plurality of second connectors are disposed to have a pitch and a width which are less than a pitch and a width of the plurality of first connectors;
a plurality of first connection pads disposed on a portion of one surface of the interconnection structure layer overlapping with the at least one second die to be directly connected to first ends of the first and second redistribution patterns, wherein the plurality of second connectors are mounted on the plurality of first connection pads; and
a plurality of second connection pads disposed on the other portion of the one surface of the interconnection structure layer non-overlapping with the first connectors to have a pitch which is greater than a pitch of the first connection pads, wherein some of the second connection pads are directly connected to second ends of the second redistribution patterns and the others of the second connection pads are directly connected to first ends of the third redistribution patterns,
wherein the plurality of first connectors are mounted on the second connection pads.

5. The semiconductor package of claim 4, further comprising:
a plurality of third connectors disposed between the first die and the interconnection structure layer to electrically connect the first die to the interconnection structure layer, wherein the plurality of third connectors are disposed to have a pitch and a width which are less than a pitch and a width of the plurality of first connectors; and
a plurality of third connection pads disposed on a surface of the interconnection structure layer opposite to the first connectors and directly connected to second ends of the first and third redistribution patterns, wherein the third connectors are mounted on the third connection pads,
wherein the third connection pads are disposed on a surface of the interconnection structure layer opposite to the first connection pads.

6. The semiconductor package of claim 1,
wherein the first redistribution patterns provide signal paths between the first die and the at least one second die;
wherein the second redistribution patterns provide signal paths between the at least one second die and the package substrate;
wherein the third redistribution patterns provide signal paths between the first die and the package substrate; and
wherein the first to third redistribution patterns provide independent paths.

7. The semiconductor package of claim 1,
wherein the first die includes a microprocessor; and
wherein the at least one second die includes a high bandwidth memory (HBM) device.

8. The semiconductor package of claim 1, wherein each of the plurality of first connectors has a shape of a ball.

9. The semiconductor package of claim 1, wherein the cavity of the package substrate is disposed so that the at least one second die overlaps with a central portion of the first die.

10. The semiconductor package of claim 9, wherein the at least one second die includes a plurality of second die which are disposed side-by-side in the cavity.

11. The semiconductor package of claim 1,
wherein the cavity includes a plurality of sub-cavities which are spaced apart from each other; and
wherein the plurality of sub-cavities include four sub-cavities which are disposed to be adjacent to four corners of the package substrate, respectively.

12. The semiconductor package of claim 1, wherein the cavity extends to penetrate the package substrate.

13. A semiconductor package comprising:
a first die;
an interconnection structure layer electrically connected to the first die;
at least one second die disposed to overlap with a portion of the first die;
a molding part disposed on a surface of the interconnection structure layer to surround the at least one second die;
a plurality of through mold vias penetrating the molding part; and
a package substrate electrically connected to the plurality of through mold vias,
wherein the interconnection structure layer includes:
first redistribution patterns extending substantially in a vertical direction to electrically connect the first die to the at least one second die;
second redistribution patterns extending substantially in a horizontal direction to electrically connect the at least one second die to some of the plurality of through mold vias; and
third redistribution patterns electrically connecting the first die to the others of the plurality of through mold vias.

14. A semiconductor package comprising:
a first die:
at least one second die electrically connected to the first die;
an interconnection structure layer electrically connected to the first die;
a plurality of first connectors disposed on the interconnection structure layer; and
a package substrate electrically connected to the plurality of first connectors,
wherein the package substrate has a cavity and the at least one second die is at least partially disposed in the cavity,
wherein the interconnection structure layer includes signal paths electrically connected to the first die and to the at least one second die, and
wherein the at least one second die are positioned to minimize a length of the signal paths.

15. The semiconductor package of claim 14,
wherein the signal paths include first redistribution patterns extended substantially in a vertical direction to electrically connect the first die and to the at least one second die.

16. The semiconductor package of claim 14,
wherein the first die at least partially overlaps, vertically, with the at least one second die.

17. The semiconductor package of claim 14,
wherein the first die and the at least one second die each include an interface physical layer, and
wherein the signal paths are electrically connected to the interface physical layer of the first die and to the interface physical layer of the at least one second die.

18. The semiconductor package of claim 15, wherein the interconnection structure layer includes:
second redistribution patterns extending substantially in a horizontal direction to electrically connect the at least one second die to some of the plurality of first connectors; and
third redistribution patterns electrically connecting the first die to the others of the plurality of first connectors.

19. The semiconductor package of claim 14,
wherein a distance between the package substrate and the interconnection structure layer is less than a height of the at least one second die.

20. The semiconductor package of claim 14, further comprising:
a plurality of second connectors disposed between the at least one second die and the interconnection structure layer to electrically connect the at least one second die to the interconnection structure layer, wherein the plurality of second connectors are disposed to have a pitch and a width which are less than a pitch and a width of the plurality of first connectors.
